(19) United States
(12) Patent Application Publication
(10) Pub. No.: US 2025/0038116 A1
(43) Pub. Date: Jan. 30, 2025

(54) PRINTED CIRCUIT BOARD

(71) Applicant: SAMSUNG ELECTRO-MECHANICS CO., LTD., Suwon-si (KR)

(72) Inventors: Da Hee JOUNG, Suwon-si (KR); Bong Wan KOO, Suwon-si (KR); Jee Hoon KIM, Suwon-si (KR)

(73) Assignee: SAMSUNG ELECTRO-MECHANICS CO., LTD., Suwon-si (KR)

(21) Appl. No.: 18/581,708

(22) Filed: Feb. 20, 2024

(30) Foreign Application Priority Data
Jul. 25, 2023 (KR) 10-2023-0096506

(51) Int. Cl. H01L 23/538; H01L 21/48; H01L 23/00; H01L 25/18; H10B 80/00

(52) U.S. Cl. CPC H01L 23/5386; H01L 21/4857; H01L 23/5383; H01L 24/13; H01L 24/14; H01L 24/16; H01L 25/18; H01L 2224/13111; H01L 2224/13124; H01L 2224/13147; H01L 2224/1403; H01L 2224/16227; H01L 2924/014; H01L 2924/10252; H01L 2924/10253; H01L 2924/10329; H01L 2924/1431; H01L 2924/1432; H01L 2924/1433; H01L 2924/1436; H01L 2924/1438; H01L 2924/145; H10B 80/00

(57) ABSTRACT

A printed circuit board may include: a first substrate unit including a plurality of build-up insulating layers and a plurality of build-up wiring layers respectively disposed on or in the plurality of build-up insulating layers; and a second substrate unit including a glass layer, first and second wiring layers disposed above and below the glass layer, respectively, an insulating layer disposed above the glass layer, and a third wiring layer disposed above the insulating layer, wherein the second substrate unit is stacked on the first substrate unit or embedded in the first substrate unit, wherein an average pitch of circuits of each of the first to third wiring layers is lower than an average pitch of circuits of each of the plurality of build-up wiring layers.

### CROSS-REFERENCE TO RELATED APPLICATION(S)

This application claims benefit of priority to Korean Patent Application No. 10-2023-0096506 filed on Jul. 25, 2023, in the Korean Intellectual Property Office, the disclosure of which is incorporated herein by reference in its entirety.

### TECHNICAL FIELD

The present disclosure relates to a printed circuit board.

In a Multi-Chip Package (MCP), instead of implementing a microcircuit for connecting heterogeneous semiconductors in a package substrate, technology using silicon interposer utilizing a silicon (Si)-based technology or Embedded Multi-Die Interconnect Bridge (EMIB) are being developed, but there may be a problem that costs thereof is very high.

On the other hand, recently, package technology has attempted to use glass materials by breaking away from the use of organic materials as a traditional substrate manufacturing method, to improve warpage issues at a package level, but a glass substrate may have a high risk of damage to the substrate during a process such as handling, and thus yield thereof may decrease.

### SUMMARY

An aspect of the present disclosure is to provide a printed circuit board including a microcircuit that may be manufactured at lower cost than a silicon interposer.

Another aspect of the present disclosure is to provide a printed circuit board that may improve mass productivity by improving yield problems due to treating and handling of glass boards.

One of various solutions proposed by the present disclosure is to manufacture a microcircuit board by forming a wiring layer including a microcircuit in a glass layer and an insulating layer using a first detachable carrier, and to then to perform a build-up process on a microcircuit board manufactured using a second detachable carrier to implement a multilayer substrate.

According to an aspect of the present disclosure, a printed circuit board may include: a first substrate unit including a plurality of build-up insulating layers and a plurality of build-up wiring layers respectively disposed on or in the plurality of build-up insulating layers, each of the plurality of build-up wiring layers including circuits; and a second substrate unit including a glass layer, a first wiring layer and a second wiring layer disposed on a first surface and a second surface of the glass layer, respectively, an insulating layer disposed on the glass layer, and a third wiring layer disposed on the insulating layer, each of the first to third wiring layers including circuits, wherein the second substrate unit is stacked on the first substrate unit or embedded in the first substrate unit, wherein the first surface of the glass layer opposes the second surface of the glass layer, and wherein an average pitch of the circuits of each of the first to third wiring layers is lower than an average pitch of the circuits of each of the plurality of build-up wiring layers.

According to an aspect of the present disclosure, a printed circuit board may include: a first substrate unit comprising a plurality of build-up insulating layers and a plurality of build-up wiring layers respectively disposed on or in the plurality of build-up insulating layers; and a second substrate unit comprising a glass layer, a first wiring layer and a second wiring layer disposed on a first surface and a second surface of the glass layer, respectively, an insulating layer disposed on the first surface of the glass layer, and a third wiring layer disposed on a surface of the insulating layer, wherein the first surface of the glass layer opposes the second surface of the glass layer, wherein the second substrate unit is stacked on or embedded in the first substrate unit, and wherein a total thickness of the plurality of build-up insulating layers is thicker than a thickness of the insulating layer.

According to an aspect of the present disclosure, a printed circuit board may include: a glass layer; a first insulating layer disposed on a first surface of the glass layer; a second insulating layer disposed on a second surface of the glass layer, wherein the second surface of the glass layer opposes the first surface of the glass layer; a first wiring layer disposed between the glass layer and the first insulating layer; a second wiring layer disposed on the second insulating layer; and a first via layer penetrating through the glass layer and the second insulating layer collectively and connecting the first and second wiring layers.

One effect of the present disclosure is to provide a printed circuit board including a microcircuit that may be manufactured at lower costs than a silicon interposer.

Another effect of the present disclosure is to provide a printed circuit board that may increase mass productivity by improving yield problems due to treating and handling of a glass substrate.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating a case in which a BGA package is mounted on a main board of an electronic device;

FIG. 4 is a cross-sectional view schematically illustrating a case in which a silicon interposer package is mounted on a main board;

FIG. 5 is a cross-sectional view schematically illustrating a case in which an organic interposer package is mounted on a main board;

FIG. 6 is a cross-sectional view schematically illustrating an example of a printed circuit board;

FIGS. 7A to 7J are cross-sectional views schematically illustrating an example of manufacturing a second substrate unit in FIG. 6;

FIGS. 8A to 8F are cross-sectional views schematically illustrating an example of manufacturing the printed circuit board in FIG. 6;

FIG. 9 is a cross-sectional view schematically illustrating a modified example of the printed circuit board in FIG. 6;

FIG. 10 is a cross-sectional view schematically illustrating another example of a printed circuit board;

FIGS. 11A to 11G are cross-sectional views schematically illustrating an example of manufacturing the printed circuit board in FIG. 10;

FIG. 12 is a cross-sectional view schematically illustrating a modified example of the printed circuit board in FIG. 10;

FIG. 13 is a cross-sectional view schematically illustrating another example of a printed circuit board;

FIGS. 14A to 14J are process cross-sectional views schematically illustrating an example of manufacturing a second substrate unit in FIG. 13;

FIGS. 15A to 15F are process cross-sectional views schematically illustrating an example of manufacturing the printed circuit board in FIG. 13;

FIG. 16 is a cross-sectional view schematically illustrating a modified example of the printed circuit board in FIG. 13;

FIG. 17 is a cross-sectional view schematically illustrating another example of a printed circuit board;

FIGS. 18A to 18G are process cross-sectional views schematically illustrating an example of manufacturing the printed circuit board in FIG. 17; and

FIG. 19 is a cross-sectional view schematically illustrating a modified example of the printed circuit board in FIG. 17.

### DETAILED DESCRIPTION

Hereinafter, the present disclosure will be described with reference to the accompanying drawings. In the drawings, the shape and size of the elements may be exaggerated or reduced for clearer description.

### Electronic Device

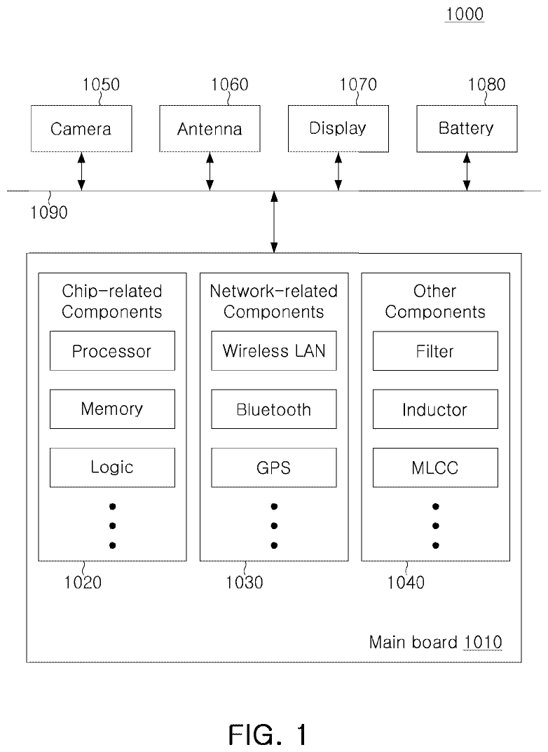

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may be in the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive (HDD)), a compact disk (CD), a digital versatile disk (DVD), or the like. Furthermore, these other electronic components may also other electronic components used for various purposes depending on a type of electronic device 1000.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

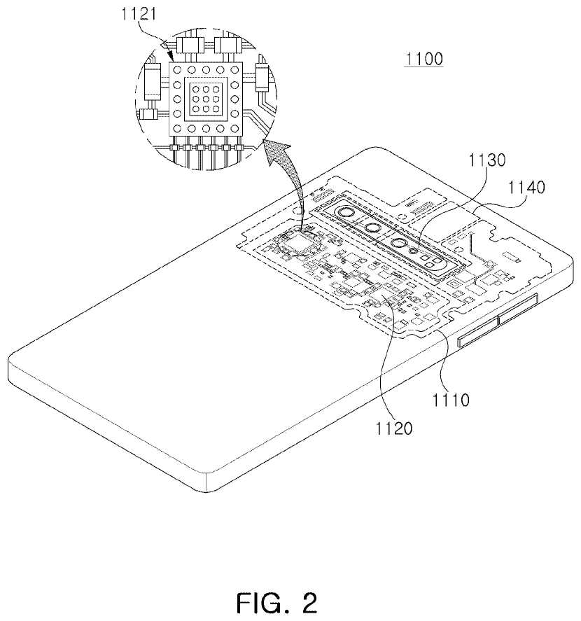

FIG. 2 is a perspective view schematically illustrating an example of an electronic device.

Referring to FIG. 2, an electronic device may be, for example, a smartphone 1100. A mother board 1110 may be accommodated in the smartphone 1100, and various components 1120 may be physically and/or electrically connected to the mother board 1110. Furthermore, other components that may or may not be physically and/or electrically connected to the mother board 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may be in the form of a printed circuit board in which an electronic component including an active component and/or a passive component is mounted on a surface. Alternatively, the component package 1121 may be in the form of a printed circuit board in which an active component and/or a passive component are embedded. On the other hand, the electronic device is not necessarily limited to the smartphone 1100, and may be other electronic devices as described above.

### Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

Hereinafter, a semiconductor package including an interposer manufactured by such packaging technology will be described in more detail with reference to the drawings.

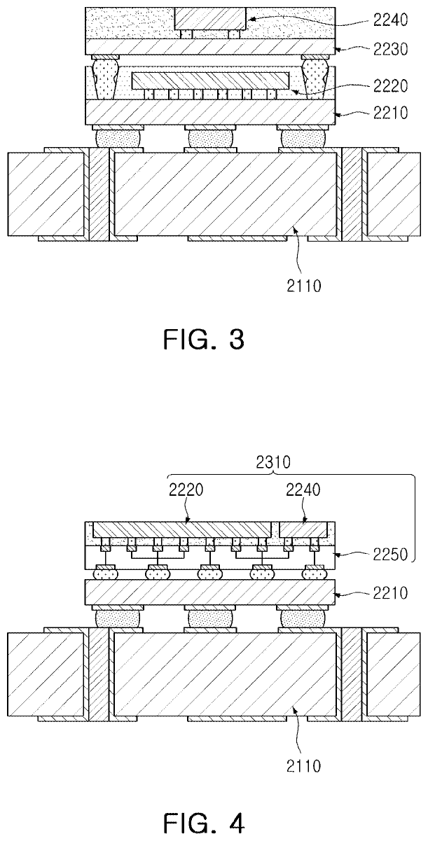

FIG. 3 is a cross-sectional view schematically illustrating a case in which a BGA package is mounted on a main board of an electronic device.

Among semiconductor chips, chips provided in an application specific integrated circuit (ASIC), such as a graphics processing unit (GPU), are significantly expensive, and thus, it may be greatly decisive to perform a packaging in high yield. To this end, a ball grid array (BGA) substrate 2210, capable of redistributing several thousands to several millions of connection pads, may be prepared before mounting a semiconductor chip, and an expensive semiconductor chip, such as a GPU 2220, may be mounted on a BGA substrate 2210 by surface mounting technology (SMT) and packaged, and then finally mounted on a main board 2110.

Meanwhile, in the case of the GPU 2220, it may be necessary to significantly reduce a signal path to a memory, such as a high bandwidth memory (HBM), and to this end, generally, a semiconductor chip such, as a HBM 240, is mounted on an interposer 2230 and then packaged, and stacked and used in the form of a package-on-package (POP) on a package on which the GPU 2220 is mounted. However, in this case, a thickness of a device may significantly increase, and there may be a limitation in reducing a signal path.

FIG. 4 is a cross-sectional view schematically illustrating a case in which a silicon interposer package is mounted on a main board.

To address the aforementioned issue, a semiconductor package 2310 including an organic interposer may be considered using an interposer technique of mounting a first semiconductor chip such as a GPU 2220 and a second semiconductor chip such as a HBM 240 side-by-side on a silicon interposer 2250 and packaging the semiconductor chips. In this case, the GPU 2220 and the HBM 2240 having several thousands to several millions of connection pads may be redistributed through the silicon interposer 2250, and may be electrically connected in a minimum path. Furthermore, when a semiconductor package 2310 including the organic interposer is mounted on a BGA substrate 2210, or the like, again and redistributed, the semiconductor package 2310 may be finally mounted on the main board 2110.

However, in the case of the silicon interposer 2250, it may be significantly difficult to form a through-silicon via (TSV), and manufacturing costs may also be high, which may be disadvantageous for large area and low costs.

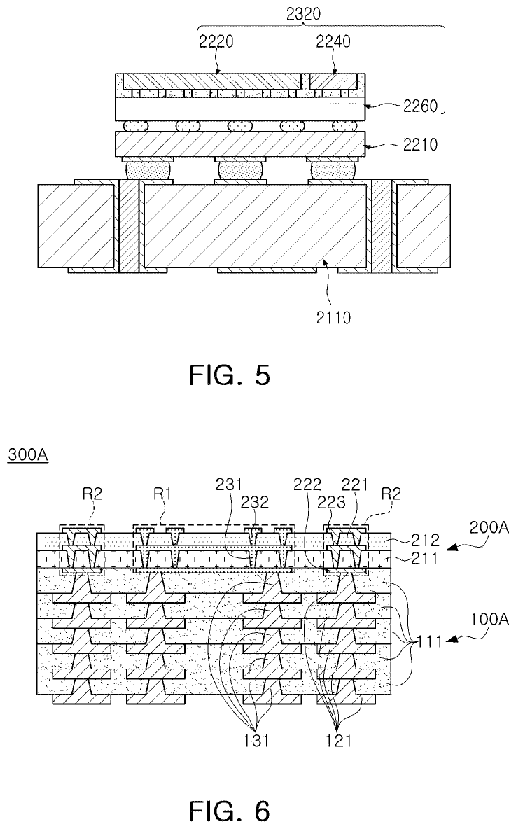

FIG. 5 is a cross-sectional view schematically illustrating a case in which an organic interposer package is mounted on a main board.

To address the aforementioned issue, an organic interposer 2260 may be used instead of a silicon interposer 2250. For example, a semiconductor package 2310 including an organic interposer may be manufactured using an interposer technique of mounting and a first semiconductor chip such as a GPU 2220 and a second semiconductor chip such as an HBM 2240 side by side on a surface of an organic interposer 2260 and packaging the semiconductor chips. In this case, it may be possible to redistribute the GPU 2220 and the HBM 2240 having several thousands or several millions of connection pads by the organic interposer 2260, and further, the GPU 2220 and the HBM 2240 may be electrically connected to each other by a significantly reduced path. Furthermore, by remounting the semiconductor package 2310 including an organic interposer on a BGA substrate 2210, and the like, and redistributing the semiconductor package 2310, the semiconductor package may be finally mounted on a main board 2110. Accordingly, it may be possible to implement a large area at low costs.

However, in the case of using the organic interposer 2260, GPU 2220 and HMB 2240 must be mounted on the organic interposer 2260 and then mounted on the BGA substrate 2210 again, and accordingly, a process thereof may be somewhat complicated, and a packaging yield may decrease.

### Printed Circuit Board

FIG. 6 is a cross-section schematically illustrating an example of a printed circuit board.

Referring to FIG. 6, a printed circuit board 300A according to an example may include a first substrate unit 100A and a second substrate unit 200A stacked on the first substrate unit 100A. The first substrate unit 100A may include a plurality of build-up insulating layers 111, a plurality of build-up wiring layers 121 respectively disposed on or in the plurality of build-up insulating layers 111, and a plurality of build-up via layers 131 respectively penetrating through at least one of the plurality of insulating layers 111. The second substrate unit 200A may include a glass layer 211, first and second wiring layers 221 and 222 respectively disposed above and below the glass layer 211, for example, on upper and lower surfaces (e.g., first and second surfaces) of the glass layer 211, an insulating layer 212 disposed above the glass layer 211, for example, on the upper surface (e.g., first surface) of the glass layer 211, a third wiring layer 223 disposed above the insulating layer 212, for example, on an upper surface of the insulating layer 212, a first via layer 231 penetrating through the glass layer 211 and connecting the first and second wiring layers 221 and 222, and a second via layer 232 penetrating through the insulating layer 212 and connecting the first and third wiring layers 221 and 223. The second substrate unit 200A may be stacked on an uppermost (or outermost) build-up insulating layer 111 so as to entirely cover a build-up insulating layer 111 disposed on an uppermost (or outermost) side, among the plurality of build-up insulating layers 111 of the first substrate unit 100A. The second substrate unit 200A may include an interconnect region R1 including a microcircuit for die-to-die connection and a wiring region R2 for die-to-substrate connection.

In this case, each of the first to third wiring layers 221, 222 and 223 of the second substrate unit 200A may include a circuit having relatively higher density than each of the plurality of build-up wiring layers 121 of the first substrate unit 100A. For example, including a circuit having relatively higher density may denote including a relatively fine circuit. For example, each of the first to third wiring layers 221, 222 and 223 may have a thickness, a line/space, pitch, and the like, which are relatively smaller than each of the plurality of build-up wiring layers 121. For example, an average pitch of each circuit of the first to third wiring layers 221, 222 and 223 may be smaller than an average pitch of each circuit of the plurality of build-up wiring layers 121. The average pitch of the circuit may be determined based on each trace pattern. Furthermore, an average separation distance between adjacent layers between the first to third wiring layers 221, 222 and 223 may be smaller than an average separation distance between adjacent layers between the plurality of build-up wiring layers 121. Furthermore, a thickness of each of the glass layer 211 and the insulating layer 212 may be thinner than a thickness of each of the plurality of build-up insulating layers 111. Additionally, a total thickness of the plurality of build-up insulating layers 111 may be thicker than a thickness of the insulating layer 212. Additionally, the total number of layers of the plurality of build-up insulating layers 111 may be greater than the number of layers of the insulating layer 212. In some embodiments, the plurality of build-up insulating layers 111 may have more layers than the insulating layer.

In this manner, the printed circuit board 300A according to an example forms a second substrate unit 200A that may be used as a microcircuit board capable of die-to-die interconnection by forming first to third wiring layers 221, 222 and 223 including microcircuits on the glass layer 211 and the insulating layer 212. Accordingly, the printed circuit board 300A may replace conventional silicon interposers, etc., and may be manufactured at lower costs. Furthermore, since the glass layer 211 is included, it may be possible to manufacture a substrate with a low coefficient of thermal expansion and high modulus as compared to a typical organic substrate, and the substrate may be made thinner. Furthermore, a glass-organic hybrid substrate may be implemented by combining the glass layer 211 with the insulating layer 212, thereby yield problems caused by treating and handling the substrate and increasing mass productivity. Additionally, on an opposite side thereof, a first substrate unit 100A of a multilayer substrate including a plurality of build-up insulating layers 111 and a plurality of build-up wiring layers 121 is formed through a build-up process. Therefore, the first substrate unit 100A may be used as a multilayer package substrate.

Meanwhile, each of the first and second via layers 231 and 232 may be tapered in opposite directions to each of the plurality of build-up via layers 131 on a cross-section. For example, as in the process described below, when forming a second substrate unit 200A using a first detachable carrier, the insulating layer 212 may be stacked in only one direction based on the glass layer 211, and in the process, first and second via layers 231 and 232 may be formed. Additionally, when forming the first substrate unit 100A on the second substrate unit 200A0 using the second detachable carrier, a plurality of build-up insulating layers 111 may be stacked only in a direction opposite to a direction in which the insulating layer 212 is stacked based on the glass layer 211, and in the process, a plurality of build-up via layers 131 may be formed. Accordingly, each of the first and second via layers 231 and 232 may be tapered in opposite directions to each of the plurality of build-up via layers 131 on a cross-section.

Meanwhile, a width of an upper end (e.g., first end) of each via of the first and second via layers 231 and 232 on a cross-section may be narrower than a width of a lower end (e.g., first end) of each via of the plurality of build-up via layers 131 on a cross-section. Additionally, an average separation distance between the vias of each of the first and second via layers 231 and 232 may be smaller than an average separation distance between the vias of each of the plurality of build-up via layers 131. For example, the first to third wiring layers 221, 222 and 223 may be formed to have a relatively finer and higher density than the plurality of build-up wiring layers 121, and accordingly, the first and second via layers 231 and 232 connected to the first to third wiring layers 221, 222 and 223 may be formed to have a relatively finer and higher density than the plurality of build-up via layers 131 connected to the plurality of build-up wiring layers 121.

Meanwhile, the first and second wiring layers 221 and 222 and the first via layer 231 may be in direct contact with the glass layer 211. For example, the first and second wiring layers 221 and 222 and the first via layer 231 may be formed directly on the glass layer 211, and accordingly, a separate insulating material or resin material may not be disposed between each of the first and second wiring layers 221 and 222 and the glass layer 211, and between the first via layer 231 and the glass layer 211. Since the first wiring layer 221 and the first via layer 231 are formed integrally with each other, boundaries thereof may not be distinct from each other at the connection portion, but since the second wiring layer 222 and the first via layer 231 are each formed through a separate plating process, boundaries thereof may be distinct from each other in a connection portion thereof.

Hereinafter, components of the printed circuit board 300A according to an embodiment will be described in more detail with reference to the drawings.

Each of the plurality of insulating layers 111 may include an insulating material. The insulating material may include a thermosetting resin such as an epoxy resin, a thermoplastic resin such as polyimide, or materials including an inorganic filler, an organic filler, and/or a glass fiber (Glass Fiber, Glass Cloth, or Glass Fabric) along with these resins. For example, the insulating material may be a non-photosensitive insulating material such as Ajinomoto Build-up Film (ABF) or Prepreg (PPG), but the present disclosure is not limited thereto, and other polymer materials may be used. Additionally, the insulating material may be a photosensitive insulating material such as Photoimageable Dielectric (PID). The plurality of insulating layers 111 may include substantially the same insulating materials, or may include insulating materials different from each other.

Each of the plurality of build-up wiring layers 121 may include metal. The metal may include copper (Cu), aluminum (Al), silver (Ag), tin (Sn), gold (Au), nickel (Ni), lead (Pb), titanium (Ti), and/or alloys thereof. The metal may include copper (Cu), but the present disclosure is not limited thereto. Each of the plurality of build-up wiring layers 121 may perform various functions depending on the design. For example, the plurality of build-up wiring layers 121 may include a signal pattern, a power pattern, and a ground pattern. Each of these patterns may have various forms such as a trace, a plane, and a pad. The plurality of build-up wiring layers 121 may each include an electroless plating layer (or chemical copper) and an electrolytic plating layer (or electrolytic copper). Alternatively, the plurality of build-up wiring layers 121 may include a metal foil (or copper foil) and an electrolytic plating layer (or electrolytic copper). Alternatively, the plurality of build-up wiring layers 121 may include a metal foil (or copper foil), an electroless plating layer (or chemical copper), and an electrolytic plating layer (or electrolytic copper). A sputtering layer may be included instead of an electroless plating layer (or chemical copper), and both thereof may be included if necessary.

Each of the plurality of build-up via layers 131 may include metal. The metal may include copper (Cu), aluminum (Al), silver (Ag), tin (Sn), gold (Au), nickel (Ni), lead (Pb), titanium (Ti), and/or alloys thereof. The metal may include copper (Cu), but the present disclosure is not limited thereto. Each of the plurality of build-up via layers 131 may include a field via filling a via hole, and may include a conformal via disposed along a wall surface of the via hole. The plurality of build-up via layers 131 may perform various functions according to the design. For example, the plurality of build-up via layers 131 may include a ground via, a power via, and a signal via. The plurality of build-up via layers 131 may have a taper shape in the same direction on a cross-section, for example, a taper shape in which a width of a lower end is wider than a width of an upper end on a cross-section. Each of the plurality of build-up via layers 131 may include an electroless plating layer (or chemical copper) and an electrolytic plating layer (or electric copper). A sputtering layer may be included instead of an electroless plating layer (or chemical copper), and both thereof may be included if necessary.

The glass layer 211 may include glass as an amorphous solid. The glass may include, for example, pure silicon dioxide (about 100% SiO₂), soda lime glass, borosilicate glass, and alumino-silicate glass. However, the present invention is not limited thereto, and an alternative glass material such as fluorine glass, phosphate glass, chalcogen glass, and the like, may also be used as the material. Other additives may also be included to form glass with specific physical properties. These additives may include not only calcium carbonate (e.g., lime) and sodium carbonate (e.g., soda), but also magnesium, calcium, manganese, aluminum, lead, boron, iron, chromium, potassium, sulfur and antimony, and carbonate and/or oxides of these and other elements.

The glass layer 211 may be a layer distinguished from an organic insulating material including glass fiber (Glass Fiber, Glass Cloth, Glass Fabric), for example, Copper Clad Laminate (CCL), Prepreg (PPG), and the like. For example, the glass layer 211 may include plate glass. The glass layer 211 may be a core layer. For example, the glass layer may be a glass core.

The insulating layer 212 may include an insulating material. The insulating material may include a thermosetting resin such as an epoxy resin, a thermoplastic resin such as polyimide, or materials including an inorganic filler, an organic filler, and/or a glass fiber (Glass Fiber, Glass Cloth, or Glass Fabric) along with these resins. For example, the insulating material may be a non-photosensitive insulating material such as Ajinomoto Build-up Film (ABF) or Prepreg (PPG), but the present disclosure is not limited thereto, and other polymer materials may be used. Additionally, the insulating material may be a photosensitive insulating material such as Photoimageable Dielectric (PID). The insulating layer 212 may include the same insulating material as the plurality of insulating layers 111, or may include different insulating materials.

Each of the first to third wiring layers 221, 222 and 223 may include metal. The metal may include copper (Cu), aluminum (Al), silver (Ag), tin (Sn), gold (Au), nickel (Ni), lead (Pb), titanium (Ti), and/or alloys thereof. The metal may include copper (Cu), but the present disclosure is not limited thereto. Each of the first to third wiring layers 221, 222 and 223 may perform various functions according to the design. For example, the first to third wiring layers 221, 222 and 223 may include a signal pattern, a power pattern, and a ground pattern. Each of these patterns may have various shapes such as a trace, a plane, and a pad. Each of a plurality of build-up wiring layers 121 may include an electroless plating layer (or chemical copper) and an electrolytic plating layer (or electric copper). Alternatively, each of the plurality of build-up wiring layers 121 may include a metal foil (or copper foil) and an electrolytic plating layer (or electric copper). Alternatively, each of the plurality of build-up wiring layers 121 may include a metal foil (or copper foil), an electroless plating layer (or chemical copper), and an electrolytic plating layer (or electric copper). A sputtering layer may be included instead of the electroless plating layer (or chemical copper), and both thereof may be included if necessary.

Each of the first and second via layers 231 and 232 may include metal. The metal may include copper (Cu), aluminum (Al), silver (Ag), tin (Sn), gold (Au), nickel (Ni), lead (Pb), titanium (Ti), and/or alloys thereof. The metal may include copper (Cu), but the present disclosure is not limited thereto. Each of the first and second via layers 231 and 232 may include a field VIA filling a via hole, but may include a conformal via disposed along a wall surface of the via hole. The first and second via layers 231 and 232 may perform various functions according to the design. For example, the first and second via layers 231 and 232 may include a ground via, a power via, and a signal via. The first and second via layers 231 and 232 may have a taper shape in the same direction on a cross-section, for example, a taper shape in which a width of an upper end is wider than a width of a lower end on a cross-section. Each of the first and second via layers 231 and 232 may include an electroless plating layer (or chemical copper) and an electrolytic plating layer (or electric copper). A sputtering layer may be included instead of an electroless plating layer (or chemical copper), and both thereof may be included if necessary.

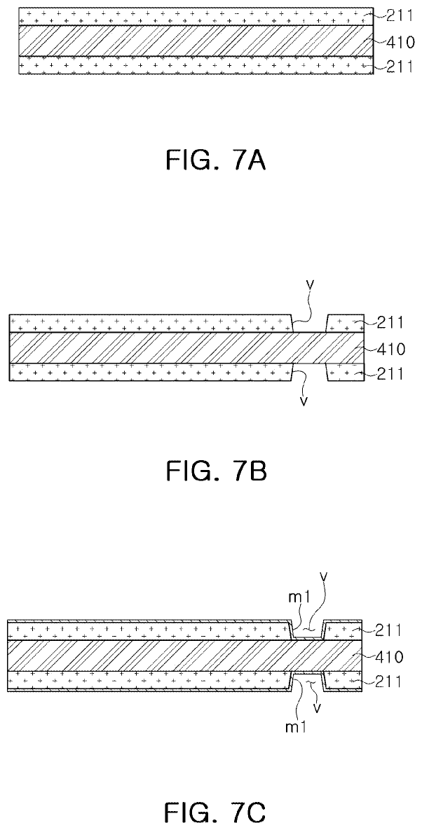

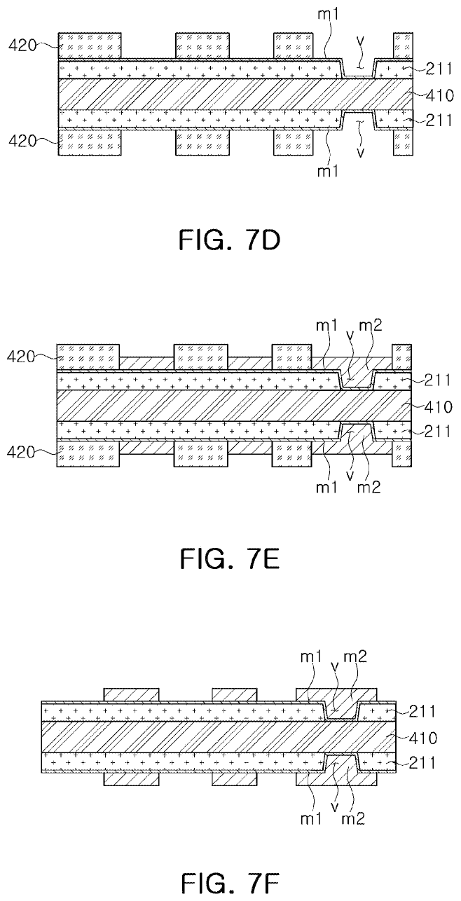

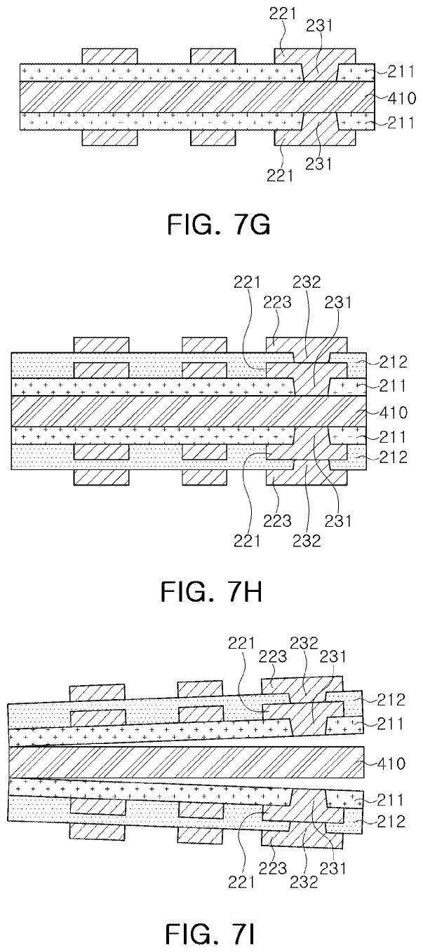

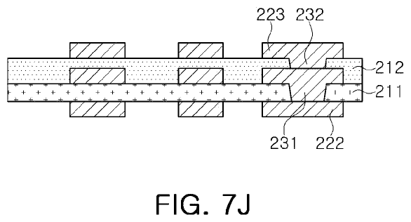

FIGS. 7A to 7J are process cross-sectional views schematically illustrating an example of manufacturing the second substrate unit in FIG. 6.

Referring to FIG. 7A, a first detachable carrier 410 is prepared. The first detachable carrier 410 may have a multilayer structure including, for example, a core layer, copper foil stacked on both surfaces of the core layer, a bonding layer stacked on the copper foil, and a metal layer stacked on the bonding layer. Next, a glass layer 211 is stacked on the first detachable carrier 410.

Referring to FIG. 7B, a via hole v is processed in the glass layer 211 using a drill. In this case, the metal layer may serve as a stopper.

Referring to FIG. 7C, a seed layer m1 is formed. The seed layer m1 may cover a wall surface of the via hole v, a surface of the glass layer 211, and an exposed portion of the first detachable carrier 410. The seed layer m1 may be formed by electroless plating, for example, chemical copper. Alternatively, the seed layer m1 may be formed by sputtering.

Referring to FIG. 7D, after forming a dry film 420, the dry film 420 is patterned through a photolithography process.

Referring to FIG. 7E, a plating layer m2 is formed. The plating layer m2 may be formed by electrolytic plating, for example, electrolytic copper.

Referring to FIG. 7F, the dry film 420 is removed. The dry film 420 may be removed using a stripping solution.

Referring to FIG. 7G, the seed layer m1 formed in areas other than an area in which the plating layer m2 is formed is removed by etching. Through a series of processes, a first wiring layer 221 and a first via layer 231 may be formed in the glass layer 211.

Referring to FIG. 7H, an insulating layer 212 is formed on the glass layer 211, and a via hole processing process, a seed layer forming process and a plating layer forming process are repeated to form a third wiring layer 223 and a second via layer 232. The insulating layer 212 may be formed by stacking and curing an insulating film in an uncured film state, or by applying and curing a material for forming the insulating layer 212. The via hole may be formed through laser processing.

Referring to FIG. 7I, a stacked body is separated from the first detachable carrier 410. In this case, a copper foil may be separated from a core layer, and the copper foil, an adhesive layer, a metal layer, and the like, remaining in the stacked body after separating the copper foil may be removed by an appropriate method.

Referring to FIG. 7J, a second wiring layer 222 is formed on a lower surface of the glass layer 211. The second wiring layer 222 may also be formed in a plating process using a Semi Additive Process (SAP), Modified SAP (MSAP), Tenting (TT), or the like. Then, a surface treatment may be performed as needed.

The above-described second substrate unit 200A may be formed through a series of processes. Meanwhile, in a process diagram, the shape of the pattern is expressed more simply for convenience of explanation. In this manner, in the process using the first detachable carrier 410, the first to third wiring layers 221, 222, and 223, and first and second via layers 231 and 232 may be directly formed on the glass layer 211 and the insulating layer 212, which may have the above-described technical effects.

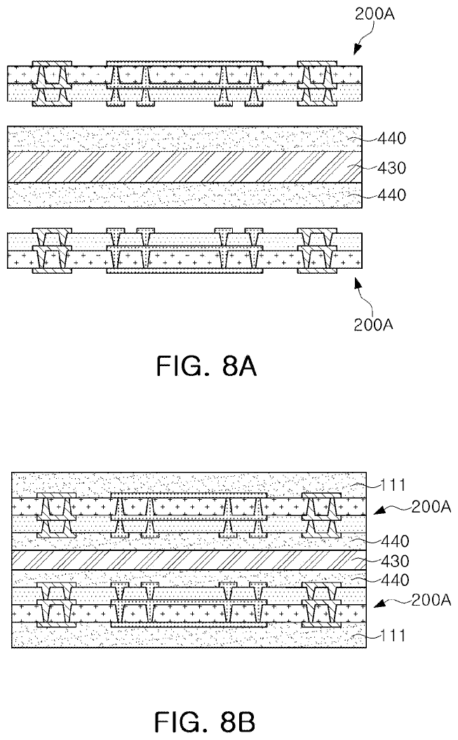

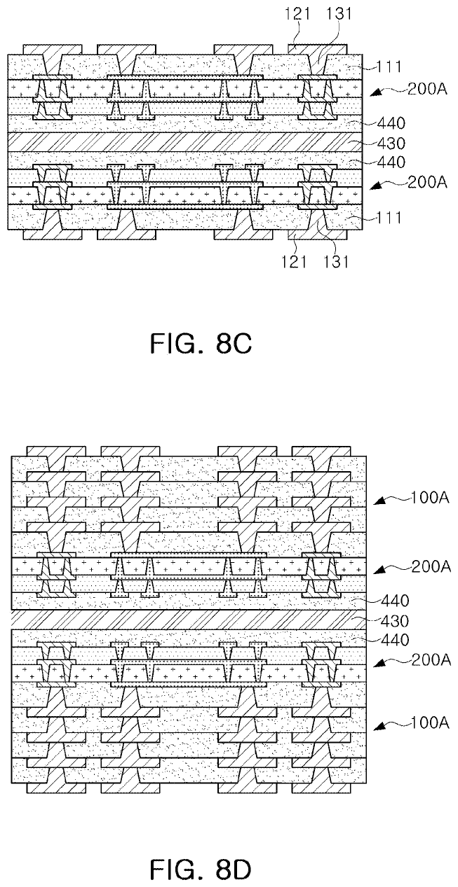

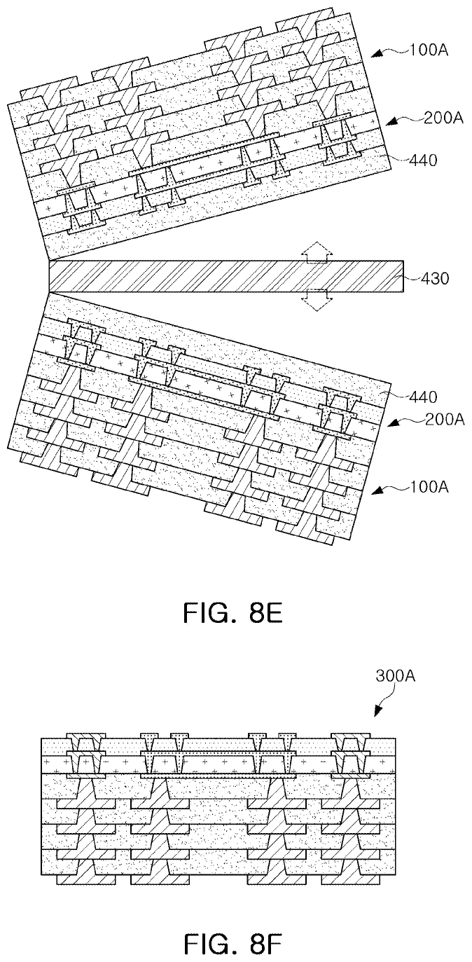

FIGS. 8A to 8F are cross-sectional views schematically illustrating an example of manufacturing the printed circuit board in FIG. 6.

Referring to FIG. 8A, a second substrate unit 200A is stacked on both sides of a second detachable carrier 430. In this case, an insulating material 440 may be disposed between the second detachable carrier 430 and the second substrate unit 200A, if necessary. The insulating material 440 may include the same material as the plurality of build-up insulating layers 111 described above.

Referring to FIG. 8B, a build-up insulating layer 111 is formed on the second substrate unit 200A. The build-up insulating layer 111 may be formed by stacking and curing an insulating film in an uncured film state, or by applying and curing a material for forming the build-up insulating layer 111.

Referring to FIG. 8C, a build-up wiring layer 121 and a build-up via layer 131 are formed on the build-up insulating layer 111. For example, after forming a via hole in the build-up insulating layer 111 by laser processing, the build-up wiring layer 121 and the build-up via layer 131 may be formed in a plating process using a Semi Additive Process (SAP), Modified SAP (MSAP), Tenting (TT), or the like.

Referring to FIG. 8D, the processes of FIGS. 8B and 8C are repeated, for example, a build-up process is performed to form a first substrate unit 100A including a plurality of build-up insulating layers 111, a plurality of build-up wiring layers 121, and a plurality of build-up via layers 131.

Referring to FIG. 8E, a stacked body of the first and second substrate units 100A and 200A is separated from the second detachable carrier 430. When the insulating material 440 is separated together, the insulating material 440 may be removed in a peeling process or the like.

Referring to FIG. 8F, the printed circuit board 300A according to the above-described embodiment may be manufactured by performing a surface treatment, an electrical inspection, sawing, and the like.

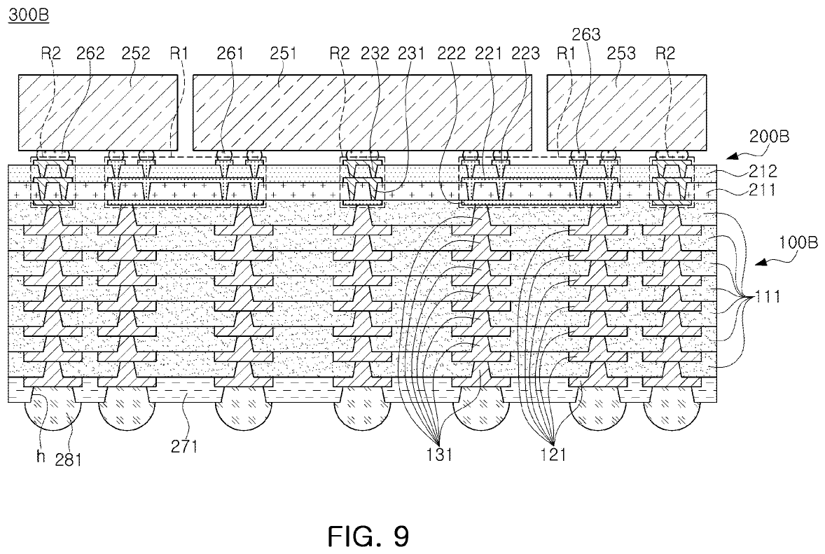

FIG. 9 is a cross-sectional view schematically illustrating a modified example of the printed circuit board in FIG. 6.

Referring to FIG. 9, a printed circuit board 300B according to a modified embodiment may configured so that a second substrate unit 200B may include an interconnect region R1 for die-to-die connection in plural form, in the printed circuit board 300A according to the above-described embodiment. Furthermore, the printed circuit board 300B may further include first to third semiconductor chips 251, 252 and 253 mounted on the second substrate unit 200B through a plurality of first to third connection members 261, 262 and 263, respectively, and electrically connected to each other through a plurality of interconnect regions R1 of the second substrate unit 200B. Furthermore, the printed circuit board 300B may further include a resist layer 271 stacked below the first substrate unit 100B. Furthermore, the printed circuit board 300B may further include a plurality of electrical connection metal bumps 281 respectively disposed on a plurality of openings h of the resist layer 271. For example, the printed circuit board 300A according to the above-described embodiment may be applied as a package board in the printed circuit board 300B according to the modified embodiment, and the printed circuit board 300B according to the modified embodiment may have a semiconductor package-type structure.

The first to third semiconductor chips 251, 252 and 253 may each include an integrated circuit (IC) die in which several hundreds to several millions of elements are integrated into one chip. In this case, the integrated circuit may be, for example, a logic chip such as a central processor (e.g., CPU), a graphics processor (e.g., GPU), a field programmable gate array (FPGA), a digital signal processor, a cryptographic processor, a microprocessor, a microcontroller, an application processor (e.g., AP), an analog-to-digital converter, an application-specific IC (ASIC) or the like, but the present disclosure is not limited thereto, and the integrated circuit may be a memory chip such as a volatile memory (e.g., DRAM), a non-volatile memory (e.g., ROM), a flash memory, a high bandwidth memory (HBM) or the like, or other types such as power management IC (PMIC). For example, the first semiconductor chip 251 may include a logic chip such as a GPU, and the second and third semiconductor chips 252 and 253 may include a memory chip such as HBM or the like.

Each of the first to third semiconductor chips 251,252 and 253 may be formed based on an active wafer, and in this case, silicon (Si), germanium (Ge), gallium arsenide (GaAs), or the like, may be used as a base material forming each body. Various circuits may be formed in the body. A connection pad may be formed on each body, and the connection pad may include a conductive material such as aluminum (Al) or copper (Cu). Each of the first to third semiconductor chips 251, 252 and 253 may be a bare die, in which case a metal bump may be disposed on the connection pad. Each of the first to third semiconductor chips 251, 252 and 253 may be a packaged die, in which case a redistribution layer may be additionally formed on the connection pad, and a metal bump may be disposed on the redistribution layer.

The first to third semiconductor chips 251, 252 and 253 may be mounted on the second substrate unit 200B through the plurality of first to third connection members 261, 262 and 263. Each of the plurality of first to third connection members 261, 262 and 263 may be formed of a low melting point metal, for example, solder such as tin (Sn)-aluminum (Al)-copper (Cu), but this is only an example and a material thereof is not particularly limited thereto. Each of the plurality of first to third connection members 261, 262 and 263 may be a ball or the like. Each of the plurality of first to third connection members 261, 262 and 263 may be formed of multiple layers or a single layer. When the plurality of first to third connection members 261, 262 and 263 are formed of multiple layers, they may include a copper pillar and solder, and when the plurality of first to third connection members 261, 262 and 263 are formed of a single layer, they may include tin-silver solder or copper, but the present disclosure is not limited thereto.

The resist layer 271 may protect internal components of the circuit board 300B. A material of the resist layer 271 is not particularly limited. For example, an insulating material may be used, and in this case, solder resist may be used as the insulating material. However, the present disclosure is not limited thereto, and ABF, or the like, may be used. The resist layer 271 may have a plurality of openings h that expose at least a portion of each of the build-up wiring layers 122 disposed on a lowermost side among the plurality of build-up wiring layers 122. A surface treatment layer may be formed on a pattern exposed through the plurality of openings h, and underbump metal may be further formed if necessary.

The plurality of electrical connection metal bumps 281 are configured to connect the printed circuit board 300B to a main board of an electronic device or another board. The plurality of electrical connection metal bumps 281 may be connected to at least a portion of a lowermost wiring layer of a substrate 110-1. If necessary, the plurality of electrical connection metal bumps 281 may be respectively disposed through a plurality of underbump metals. The plurality of electrical connection metal bumps 281 may be formed of a conductive material, for example, solder or the like, but this is only an example and a material thereof is not particularly limited thereto. Each of the plurality of electrical connection metal bumps 281 may be a ball, a pin, or the like. Each of the plurality of electrical connection metal bumps 281 may be formed of multiple layers or a single layer. When the plurality of electrical connection metal bumps 281 are formed of multiple layers, they may include a copper pillar and solder, and when the plurality of electrical connection metal bumps 281 are formed of a single layer, they may include tin-silver solder or copper, but the present disclosure is not limited thereto.

Other contents, for example, a description of the configurations of the first and second substrate units 100B and 200B of the printed circuit board 300B according to the modified embodiment are substantially the same as what was described in the printed circuit board 300A according to the above-described embodiment, and therefore, redundant description thereof will be omitted.

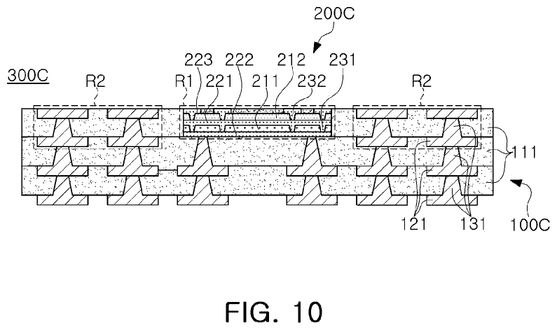

FIG. 10 is a cross-sectional view schematically illustrating another example of a printed circuit board.

Referring to FIG. 10, a printed circuit board 300C according to another embodiment may include a first substrate unit 100C and a second substrate unit 200C embedded in the first substrate unit 100C. The second substrate unit 200C may include only an interconnect region R1 in the second substrate unit 200A of the printed circuit board according to the above-described embodiment, and may have, for example, a shape of a bridge for die-to-die interconnect. The second substrate unit 200C may be configured so that an upper portion (e.g., a first outermost portion) thereof may be exposed from a build-up insulating layer 111 disposed on an uppermost side, among the plurality of build-up insulating layers 111 of the first substrate unit 100C, and a lower portion (e.g., a second outermost portion) and a side portion of the substrate unit 200 may be embedded in the plurality of build-up insulating layers 111 to be covered with the plurality of build-up insulating layers 111 of the first substrate unit 100C. The first substrate unit 100A may surround the side portion and the lower portion of the second substrate unit 200C. For example, the first substrate unit 100A may include a wiring region R2 for die-to-substrate connection.

Other contents, for example, a description of the configurations of the first and second substrate units 100C and 200C of the printed circuit board 300C according to another embodiment are substantially the same as what was described in the printed circuit board 300A according to the above-described embodiment and the printed circuit board 300B according to the above-described modified embodiment, and therefore, redundant description will be omitted.

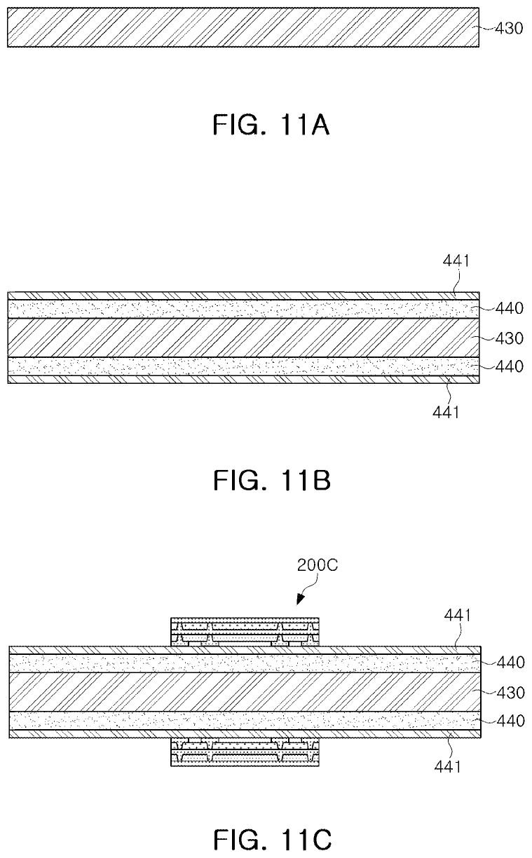

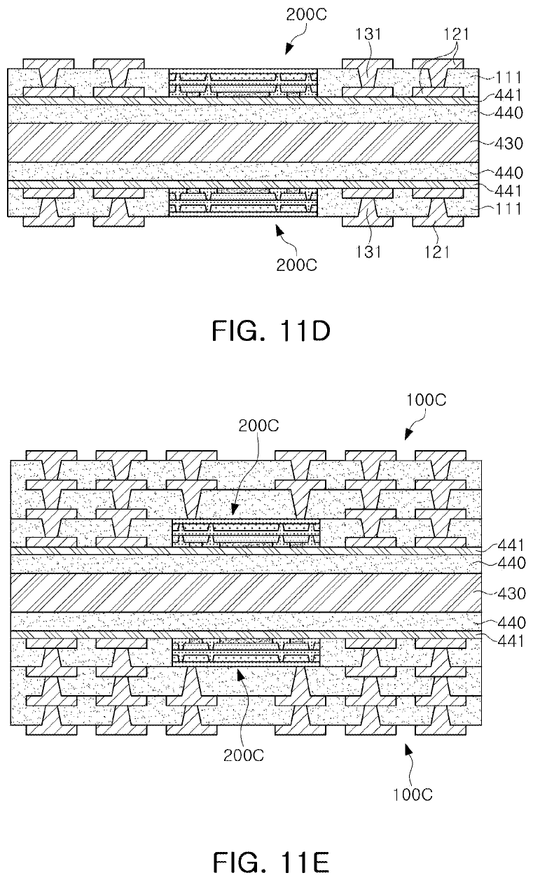

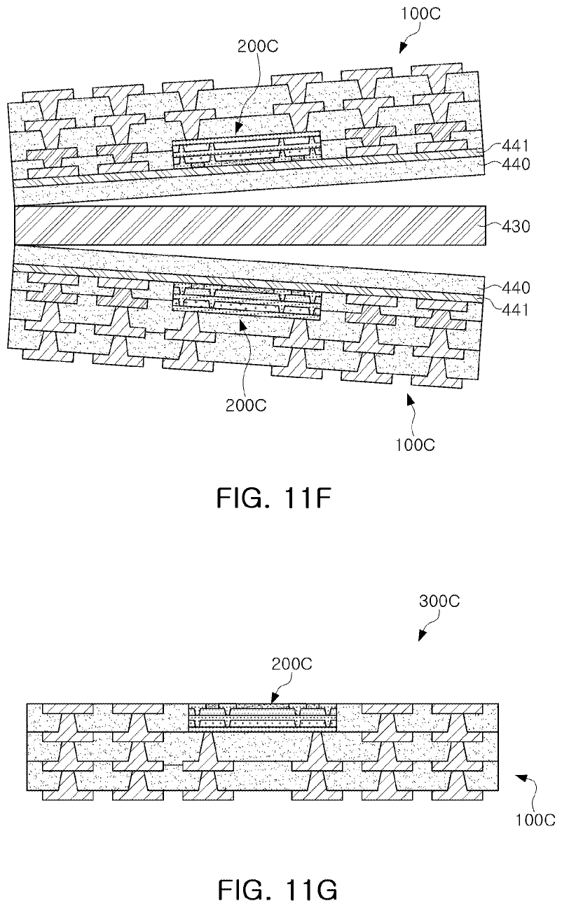

FIGS. 11A to 11G are cross-sectional views schematically illustrating an example of manufacturing the printed circuit board in FIG. 10.

Referring to FIG. 11A, a second detachable carrier 430 is prepared.

Referring to FIG. 11B, an insulating material 440 is formed on both sides of the second detachable carrier 430. If necessary, a barrier layer 441, for example, a nickel (Ni) layer, may be formed on the insulating material 440.

Referring to FIG. 11C, the second substrate unit 200C is attached onto the barrier layer 441. The second substrate unit 200C may be manufactured by referring to the processes of FIGS. 7A to 7K described above, and a sawing process may be added to manufacture the second substrate unit 200C in a shape of a bridge.

Referring to FIG. 11D, a build-up wiring layer 121 is formed on the barrier layer 441. Additionally, a build-up insulating layer 111 is formed on the barrier layer 441, and a build-up wiring layer 121 and a build-up via layer 131 are further formed on the build-up insulating layer 111. The build-up wiring layer 121 may be formed in a plating process using a Semi Additive Process (SAP), Modified SAP (MSAP), Tenting (TT), or the like. The build-up insulating layer 111 may be formed by stacking and curing an insulating film in an uncured film state, or by applying and curing a material for forming the build-up insulating layer 111. A build-up wiring layer 121 and a build-up via layer 131 further formed on the build-up insulating layer 111 may be formed by forming a via hole in the build-up insulating layer 111 by laser processing and then performing a plating process using a Semi Additive Process (SAP), MSAP (Modified SAP), Tenting (TT), or the like.

Referring to FIG. 11E, the process of FIG. 11D is repeated, for example, a build-up process is performed to form a first substrate unit 100C including a plurality of build-up insulating layers 111, a plurality of build-up wiring layers 121, and a plurality of build-up via layers 131.

Referring to FIG. 11F, a stacked body of the first and second substrate units 100C and 200C is separated from the second detachable carrier 430. When the insulating material 440 and the barrier layer 441 are separated together, the insulating material 440 may be removed in a peeling process, and the barrier layer 441 may be removed by an etching process.

Referring to FIG. 11G, a printed circuit board 300C according to another embodiment described above may be manufactured by performing a surface treatment, an electrical inspection, sawing, and the like.

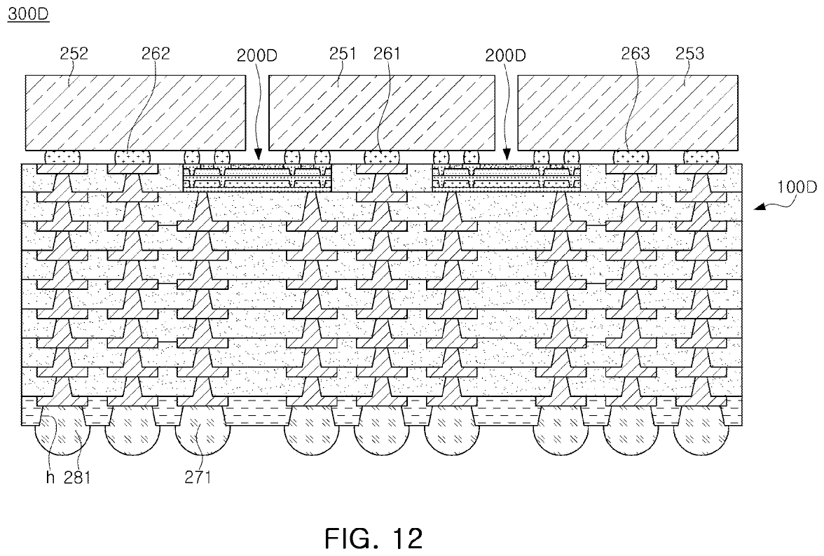

FIG. 12 is a cross-sectional view schematically illustrating a modified example of the printed circuit board in FIG. 10.

Referring to FIG. 12, a printed circuit board 300D according to the modified embodiment may be configured so that a plurality of second substrate units 200D may be embedded in a plurality of build-up insulating layers 111 of the first substrate unit 100D, respectively, in the printed circuit board 300C according to another embodiment described above. Furthermore, the printed circuit board 300D may further include first to third semiconductor chips 251, 252 and 253 respectively mounted on the second substrate unit 200D through a plurality of first to third connection members 261, 262 and 263 and electrically connected to each other through the second substrate unit 200D. Furthermore, the printed circuit board 300D may further include a resist layer 271 stacked on a lower side of the first substrate unit 100D. Furthermore, the printed circuit board 300D may further include a plurality of electrical connection metal bumps 281 respectively disposed on a plurality of openings h of the resist layer 271. For example, the printed circuit board 300C according to another embodiment described above may be applied as a package board in the printed circuit board 300D according to the modified embodiment, and the printed circuit board 300D according to the modified embodiment may have a semiconductor package-type structure.

Other contents, for example, a description of the configurations of the first and second substrate units 100D and 200D of the printed circuit board 300D according to the modified embodiment are substantially the same as what was described in the printed circuit board 300A according to the above-described embodiment, the printed circuit board 300B according to the above-described modified embodiment, and the printed circuit board 300C according to another example described above, and therefore, redundant description thereof are omitted.

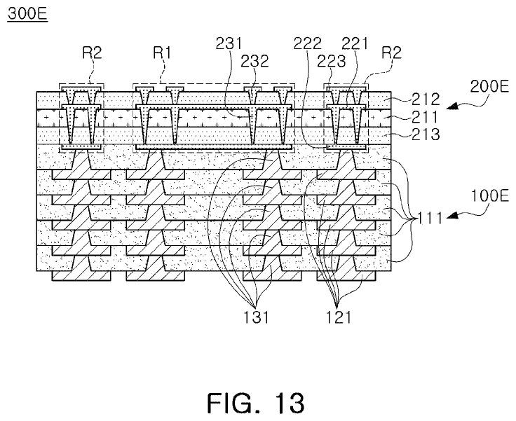

FIG. 13 is a cross-section schematically illustrating another example of a printed circuit board.

Referring to FIG. 13, a printed circuit board 300E according to another example may be configured so that a second substrate unit 200E may further include a second insulating layer 213, in the printed circuit board 300A according to the above-described embodiment. For example, the second substrate unit 200E may include a glass layer 211, a first insulating layer 212 disposed above the glass layer 211, a second insulating layer 213 disposed below the glass layer 211, a first wiring layer 221 disposed between the glass layer 211 and the first insulating layer 212, a second wiring layer 222 disposed below the second insulating layer 213, a first via layer 231 collectively penetrating through the glass layer 211 and the second insulating layer 212 and connecting the first and second wiring layers 221 and 222, a third wiring layer 223 disposed above the first insulating layer 212, and a second via layer 232 penetrating through the first insulating layer 212 and connecting the first and third wiring layers 221 and 223.

Meanwhile, the first via layer 231 may be deeper than the second via layer 232. For example, the first via layer 231 may penetrate through the glass layer 211 and the second insulating layer 213 collectively, but the second via layer 232 may penetrate through only the first insulating layer 212, and accordingly, a depth of a via hole for forming the first via layer 231 may be deeper than a depth of a via hole for forming the second via layer 232.

Meanwhile, the second insulating layer 213 may include an insulating material. The insulating material may include a thermosetting resin such as an epoxy resin, a thermoplastic resin such as polyimide, or materials including an inorganic filler, an organic filler, and/or a glass fiber (Glass Fiber, Glass Cloth, or Glass Fabric) along with these resins. For example, the insulating material may be a non-photosensitive insulating material such as Ajinomoto Build-up Film (ABF) or Prepreg (PPG), but the present disclosure is not limited thereto, and other polymer materials may be used. Additionally, the insulating material may be a photosensitive insulating material such as Photoimageable Dielectric (PID). The second insulating layer 213 may include an insulating material the same as or different from that of the first insulating layer 212.

Other contents, for example, a description of the configurations of the first and second substrate units 100E and 200E of the printed circuit board 300E according to another embodiment are substantially the same as what was described in the printed circuit board 300A according to the above-described embodiment, the printed circuit board 300B according to the above-described modified embodiment, the printed circuit board 300C according to another example described above, and the printed circuit board 300D according to the above-described modified embodiment, and therefore, redundant description thereof are omitted.

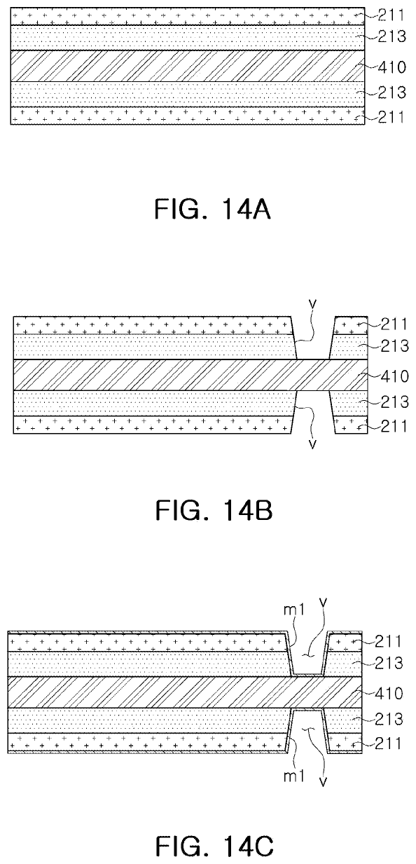

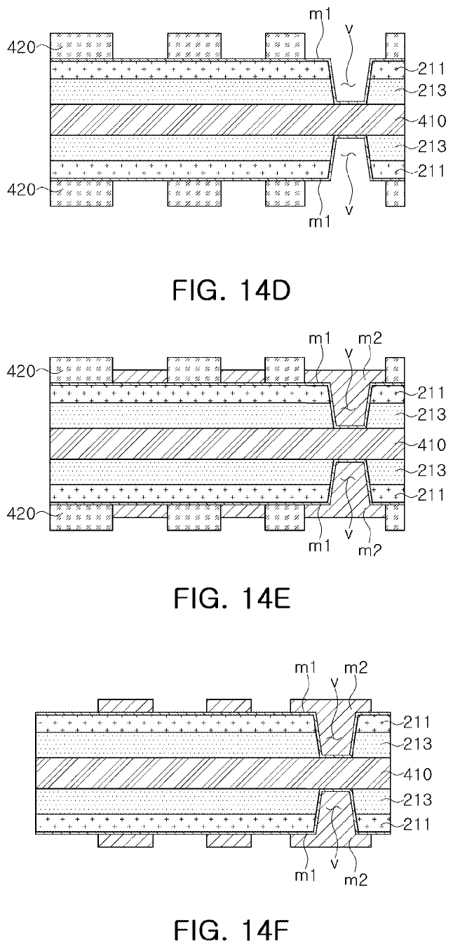

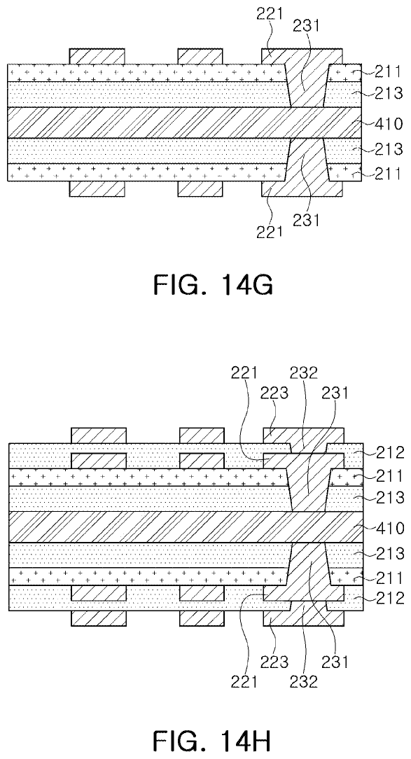

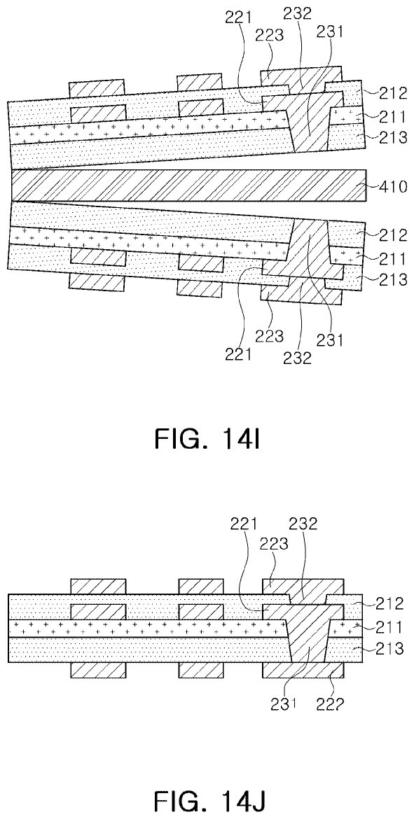

FIGS. 14A to 14J are process cross-sectional views schematically illustrating an example of manufacturing the second substrate unit in FIG. 13.

Referring to FIG. 14A, a first detachable carrier 410 is prepared. The first detachable carrier 410 may, for example, have a multilayer structure including a core layer and copper foil stacked on both surfaces of the core layer. Next, the glass layer 211 is stacked on the first detachable carrier 410 using the second insulating layer 213 as an adhesive layer.

Referring to FIG. 14B, a via hole v is processed in the glass layer 211 and the second insulating layer 213 using a drill. In this case, copper foil may serve as a stopper.

Referring to FIG. 14C, a seed layer m1 is formed. The seed layer m1 may cover a wall surface of the via hole v, a surface of the glass layer 211, and an exposed portion of the first detachable carrier 410. The seed layer m1 may be formed by electroless plating, for example, chemical copper. Alternatively, the seed layer m1 may be formed by sputtering.

Referring to FIG. 14D, after forming a dry film 420, the dry film 420 is patterned in a photolithography process.

Referring to FIG. 14E, a plating layer m2 is formed. The plating layer m2 may be formed by electrolytic plating, for example, electrolytic copper.

Referring to FIG. 14F, the dry film 420 is removed. The dry film 420 may be removed using a stripping solution.

Referring to FIG. 14G, the seed layer m1 formed in areas other than an area in which the plating layer m2 is formed is removed by etching. Through a series of processes, a first wiring layer 221 and a first via layer 231 may be formed in the glass layer 211 and the second insulating layer 213.

Referring to FIG. 14H, a first insulating layer 212 is formed on the glass layer 211, and a via hole processing process, a seed layer forming process, and a plating layer forming process are repeated to form a third wiring layer 223 and a second via layer 232. The first insulating layer 212 may be formed by stacking and curing an insulating film in an uncured film state, or by applying and curing a material for forming the insulating layer 212. The via hole may be formed by laser processing.

Referring to FIG. 14I, a stacked body is separated from the first detachable carrier 410. In this case, the copper foil may be separated from the core layer, and the copper foil remaining in the stacked body after separating the copper foil may be removed in an appropriate method such as etching.

Referring to FIG. 14J, a second wiring layer 222 is formed on a lower surface of the second insulating layer 213. The second wiring layer 222 may also be formed in a plating process using a Semi Additive Process (SAP), Modified SAP (MSAP), Tenting (TT), or the like. Then, a surface treatment may be performed as needed.

The above-described second substrate unit 200E may be formed through a series of processes. Meanwhile, in the process diagram, the shape of the pattern is expressed more simply for convenience of explanation. In this manner, in the process using the first detachable carrier 410, first to third wiring layers 221, 222 and 223 and first and second via layers 231 and 232 may be formed directly on the glass layer 211 and the first and second insulating layers 212 and 213, which may have the above-described technical effects.

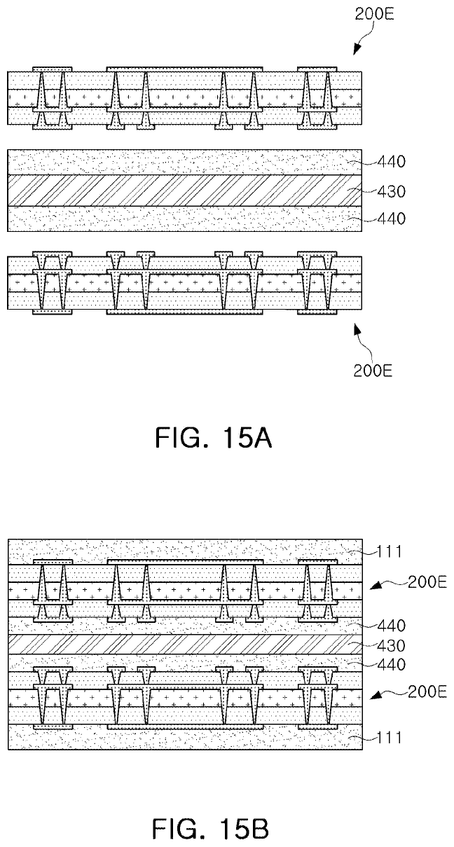

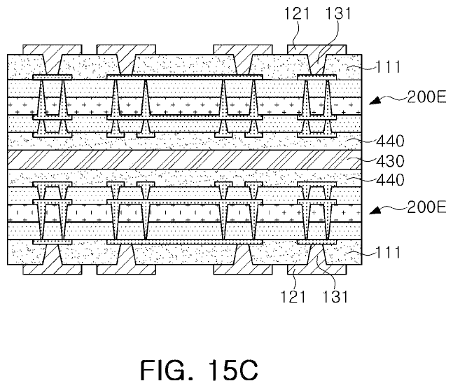

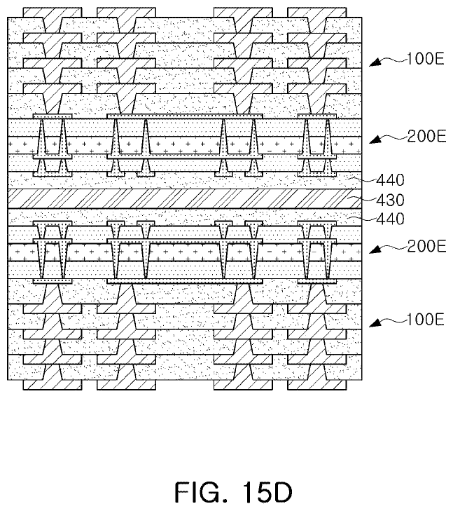

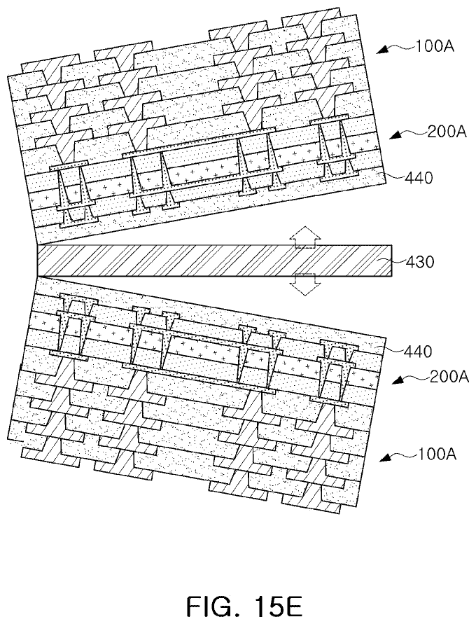

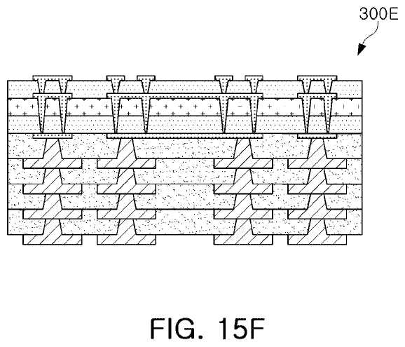

FIGS. 15A to 15F are cross-sectional views schematically illustrating an example of manufacturing the printed circuit board in FIG. 13.

Referring to FIG. 15A, a second substrate unit 200E is stacked on both sides of a second detachable carrier 430. In this case, an insulating material 440 may be disposed between the second detachable carrier 430 and the second substrate unit 200E, if necessary. The insulating material 440 may include the same material as the plurality of build-up insulating layers 111 described above.

Referring to FIG. 15B, a build-up insulating layer 111 is formed on the second substrate unit 200E. The build-up insulating layer 111 may be formed by stacking and curing an insulating film in an uncured film state, or by applying and curing a material for forming the build-up insulating layer 111.

Referring to FIG. 15C, a build-up wiring layer 121 and a build-up via layer 131 are formed on the build-up insulating layer 111. For example, after forming a via hole in the build-up insulating layer 111 by laser processing, a build-up wiring layer 121 and a build-up via layer 131 may be formed in a plating process using a Semi Additive Process (SAP), Modified SAP (MSAP), Tenting (TT), or the like.

Referring to FIG. 15D, the processes of FIGS. 15B and 15C are repeated, for example, a build-up process is performed to form a first substrate unit 100E including a plurality of build-up insulating layers 111, a plurality of build-up wiring layers 121, and a plurality of build-up via layers 131.

Referring to FIG. 15E, a stacked body of the first and second substrate units 100E and 200E is separated from the second detachable carrier 430. When the insulating material 440 is separated together, the insulating material 440 may be removed in a peeling process or the like.

Referring to FIG. 15F, a printed circuit board 300E according to another embodiment described above may be manufactured by performing a surface treatment, an electrical inspection, sawing, and the like.

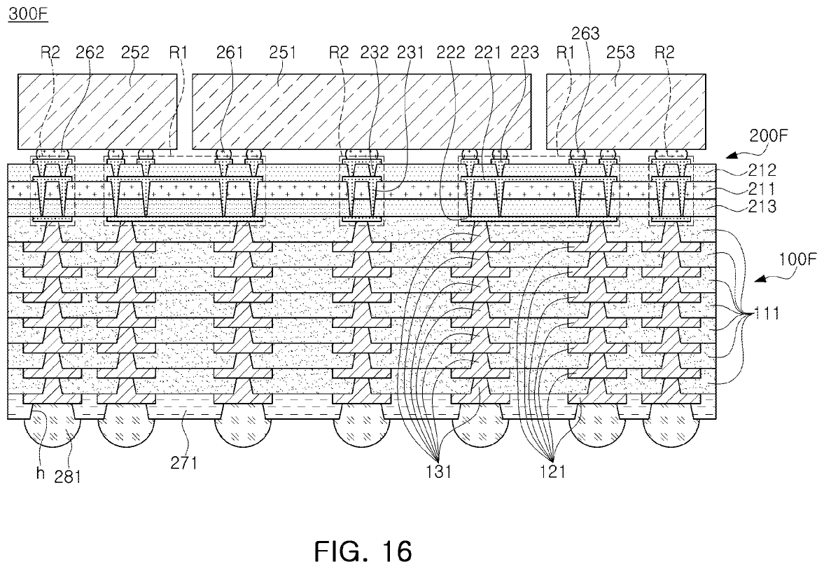

FIG. 16 is a cross-sectional view schematically illustrating a modified example of the printed circuit board in FIG. 13.

Referring to FIG. 16, a printed circuit board 300F according to a modified embodiment may be configured so that a second substrate unit 200F may include an interconnect region R1 for die-to-die connection in plural form, in the printed circuit board 300E according to another embodiment described above. The printed circuit board 300F may further include first to third semiconductor chips 251, 252 and 253 respectively mounted on the second substrate unit 200F through a plurality of first to third connection members 261, 262 and 263 and electrically connected to each other through a plurality of interconnect regions R1 of the second substrate unit 200F. Furthermore, the printed circuit board 300F may further include a resist layer 271 stacked below the first substrate unit 100F. Furthermore, the printed circuit board 300F may further include a plurality of electrical connection metal bumps 281 respectively disposed on a plurality of openings h of the resist layer 271. For example, the printed circuit board 300E according to another embodiment described above may be applied as a package board in the printed circuit board 300F according to the modified embodiment, and the printed circuit board 300F according to the modified embodiment may have a semiconductor package-type structure

Other contents, for example, a description of the configurations of the first and second substrate units 100F and 200F of the printed circuit board 300F according to the modified embodiment are substantially the same as what was described in the printed circuit board 300A according to the above-described embodiment, the printed circuit board 300B according to the above-described modified embodiment, the printed circuit board 300C according to another example described above, and the printed circuit board 300D according to the above-described modified embodiment, and the circuit board 300E according to another embodiment described above, and therefore, redundant description thereof will be omitted.

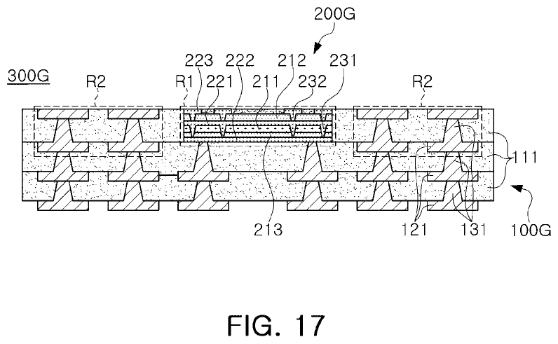

FIG. 17 is a cross-sectional view schematically illustrating another example of a printed circuit board.

Referring to FIG. 17, a printed circuit board 300G according to another embodiment may be configured so that a second substrate unit 200G may further include a second insulating layer 213, in the printed circuit board 300C according to another embodiment described above. For example, the second substrate unit 200G may include a glass layer 211, a first insulating layer 212 disposed above the glass layer 211, a second insulating layer 213 disposed below the glass layer 211, a first wiring layer 221 disposed between the glass layer 211 and the first insulating layer 212, a second wiring layer 222 disposed below the second insulating layer 213, a first via layer 231 penetrating through the glass layer 211 and the second insulating layer 212 collectively and connecting the first and second wiring layers 221 and 222, a third wiring layer 223 disposed above the first insulating layer 212, and a second via layer 232 penetrating through the first insulating layer 212 and connecting the first and third wiring layers 221 and 223.

Other contents, for example, a description of the configurations of the first and second substrate units 100G and 200G of the printed circuit board 300G according to another embodiment are substantially the same as what was described in the printed circuit board 300A according to the above-described embodiment, the printed circuit board 300B according to the above-described modified embodiment, the printed circuit board 300C according to another example described above, the printed circuit board 300D according to the above-described modified embodiment, the printed circuit board 300E according to another embodiment described above, and the printed circuit board 300F according to the above-described modified embodiment, and therefore, overlapping descriptions thereof are omitted.

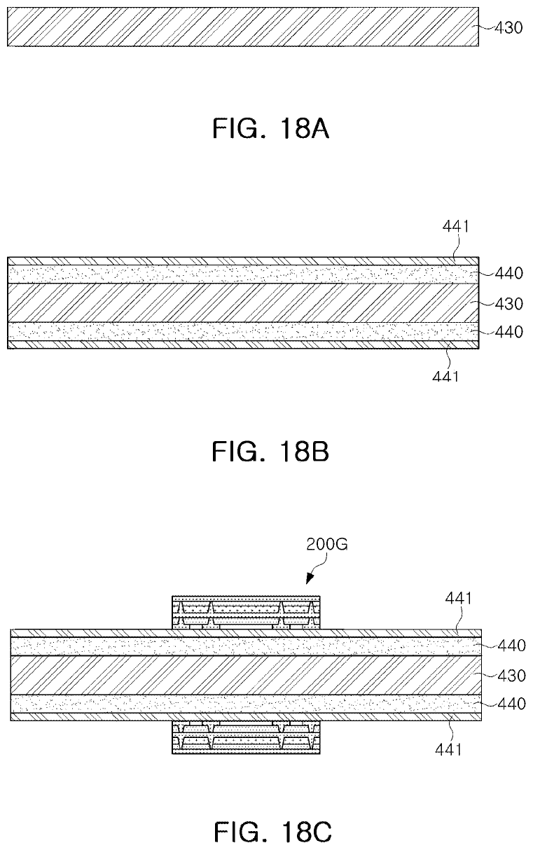

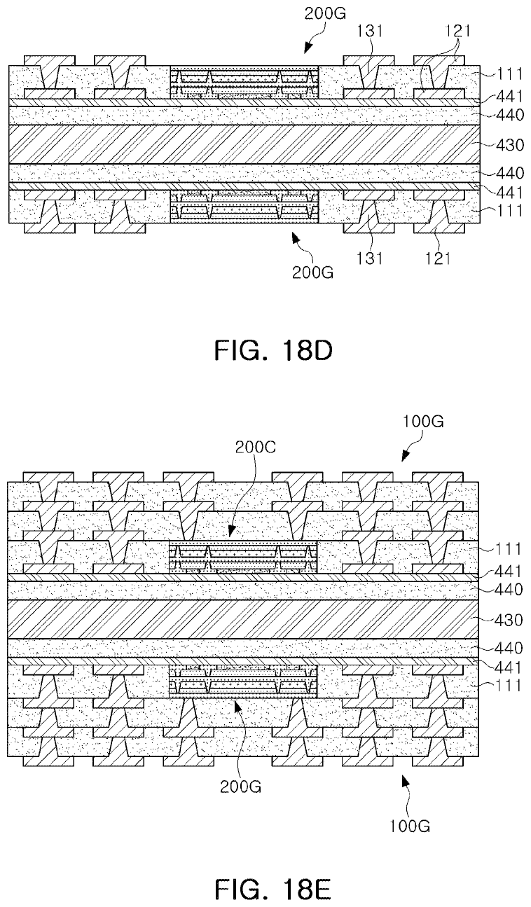

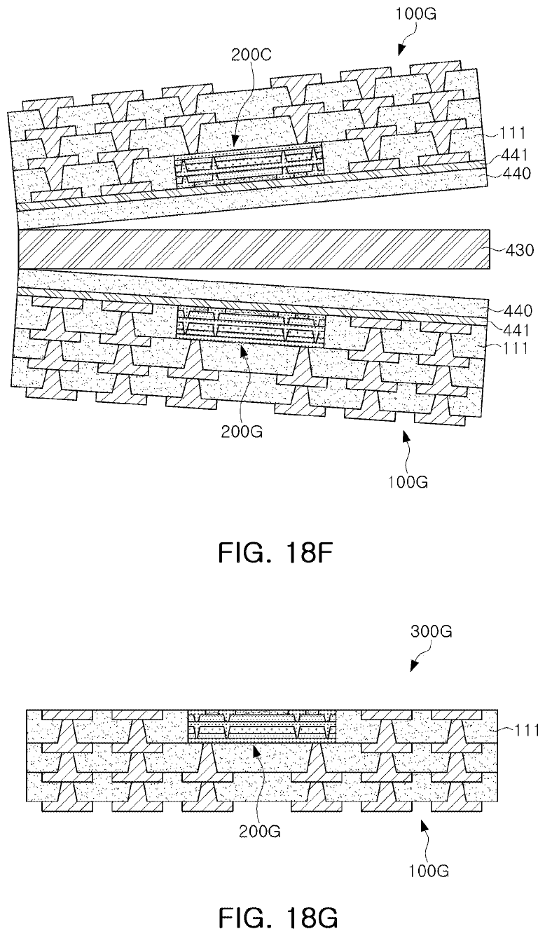

FIGS. 18A to 18G are cross-sectional views schematically illustrating an example of manufacturing the printed circuit board in FIG. 17.

Referring to FIG. 18A, a second detachable carrier 430 is prepared.

Referring to FIG. 18B, an insulating material 440 is formed on both sides of the second detachable carrier 430. If necessary, a barrier layer 441, for example, a nickel (Ni) layer, may be formed on the insulating material 440.

Referring to FIG. 18C, a second substrate unit 200G is attached on a barrier layer 441. The second substrate unit 200G may be manufactured by referring to the processes of FIGS. 14A to 14J described above. A sawing process may be added to manufacture the second substrate unit 200G in a shape of a bridge.

Referring to FIG. 18D, a build-up wiring layer 121 is formed on the barrier layer 441. Additionally, a build-up insulating layer 111 is formed on the barrier layer 441, and a build-up wiring layer 121 and a build-up via layer 131 are further formed on the build-up insulating layer 111. The build-up wiring layer 121 may be formed in a plating process using a Semi Additive Process (SAP), a Modified SAP (MSAP), Tenting (TT), or the like. The build-up insulating layer 111 may be formed by stacking or curing an insulating film in an uncured film state, or by applying and curing a material for forming the build-up insulating layer 111. The build-up wiring layer 121 and the build-up via layer 131 further formed on the build-up insulating layer 111 may be formed by forming a via hole in the build-up insulating layer 111 through laser processing and then performing a plating process using a Semi Additive Process (SAP), Modified SAP (MSAP), Tenting (TT), or the like.

Referring to FIG. 18E, the process of FIG. 18D is repeated, for example, a build-up process is performed to form a first substrate unit 100G including a plurality of build-up insulating layers 111, a plurality of build-up wiring layers 121, and a plurality of build-up via layers 131.

Referring to FIG. 18F, a stacked body of the first and second substrate units 100G and 200G is separated from the second detachable carrier 430. When the insulating material 440 and the barrier layer 441 are separated together, the insulating material 440 may be removed in a peeling process, and the barrier layer 441 may be removed in an etching process.

Referring to FIG. 18G, a surface treatment, an electrical inspection, sawing, and the like, may be performed to manufacture a printed circuit board 300G according to another embodiment described above.

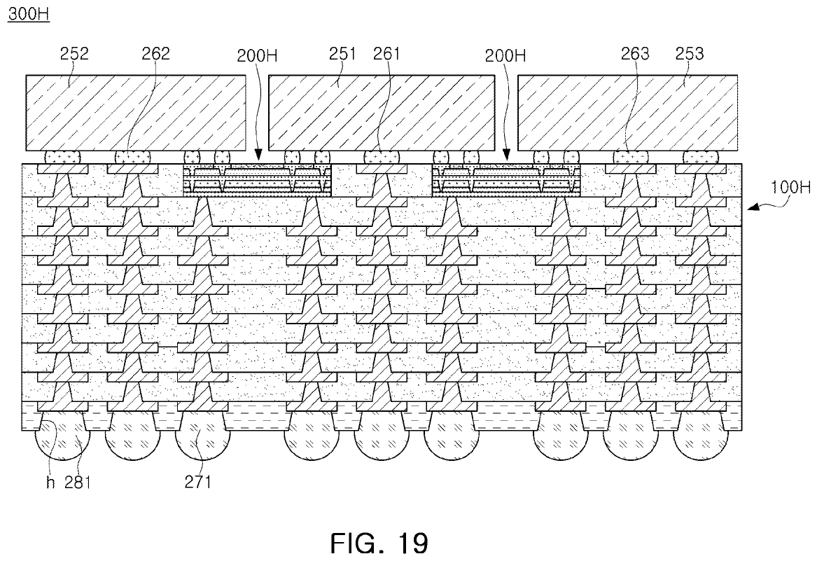

FIG. 19 is a cross-sectional view schematically illustrating a modified example of the printed circuit board in FIG. 17.

Referring to FIG. 19, a printed circuit board 300H according to a modified embodiment may be configured so that a plurality of second substrate units 200H may be respectively embedded in a plurality of build-up insulating layers 111 of the first substrate unit 100H, in the printed circuit board 300G according to another embodiment described above. The printed circuit board 300H may further include first to third semiconductor chips 251, 252 and 253 respectively mounted on a second substrate unit 200H through a plurality of first to third connection members 261, 262 and 263 and electrically connected to each other through the second substrate unit 200H. Furthermore, the printed circuit board 300H may further include may further include a resist layer 271 stacked below the first substrate unit 100H. Furthermore, the printed circuit board 300H may further include a plurality of electrical connection metal bumps 281 respectively disposed on a plurality of openings h of the resist layer 271. For example, the printed circuit board 300G according to another embodiment described above may be applied as a package board in the printed circuit board 300H according to the modified embodiment, and the printed circuit board 300H according to the modified embodiment may have a semiconductor package-type structure.

Other contents, for example, a description of the configurations of the first and second substrate units 100H and 200H of the printed circuit board 300H according to the modified embodiment, are substantially the same as what was described in the printed circuit board 300A according to the above-described embodiment, the printed circuit board 300B according to the above-described modified embodiment, the printed circuit board 300C according to another example described above, the printed circuit board 300D according to the above-described modified embodiment, the printed circuit board 300E according to another embodiment described above, the printed circuit board 300F according to the above-described modified embodiment, the printed circuit board 300G according to another embodiment described above, and therefore, redundant descriptions thereof are omitted.

In the present disclosure, a thickness, a width, a length, a pitch, and a depth may be measured with a scanning microscope or an optical microscope based on a cross-section obtained by polishing or cutting the printed circuit board, respectively. The cut cross-section may be a vertical cross-section or a horizontal cross-section, and each numerical value may be measured based on a required cut cross-section. If the numerical value is not constant, the numerical value may be determined as an average value of values measured at any of five points. A width of an upper end and/or a lower end of a via may be measured on a cross-section cut along a central axis of the via in a thickness direction of the board. A depth of the via may be measured as a distance from the upper end to the lower end of the via on a cross-section cut along the central axis of the via in a thickness direction of the board. Other methods and/or tools appreciated by one of ordinary skill in the art, even if not described in the present disclosure, may also be used.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of approximately filling, and may include, for example, a case in which some pores or voids exist.

In the present disclosure, substantially, determination may be performed by including a process error or a positional deviation occurring in a manufacturing process, and an error during measurement. For example, the expression ‘substantially vertical’ may include not only a completely vertical case but also an approximately vertical case. Furthermore, being substantially coplanar may include not only a case in which components exist on the completely same plane, but also a case in which components exist on approximately the same plane.

In the present disclosure, the same insulating material may have a meaning including the same type of insulating material as well as a case of completely the same insulating material. Accordingly, the compositions of the insulating materials are substantially identical to each other, but specific composition ratios thereof may be slightly different from each other.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, a lower side, a lower portion, and a lower surface are used to refer to a downward direction with respect to a cross-section of a drawing, and an upper side, an upper portion, and an upper surface are used to refer to an opposite direction thereof. However, this defines the direction for convenience of explanation, and the scope of the rights of the claims is not particularly limited by the description of such a direction, and the concept of upper and lower portions may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a first substrate unit including a plurality of build-up insulating layers and a plurality of build-up wiring layers respectively disposed on or in the plurality of build-up insulating layers, each of the plurality of build-up wiring layers including circuits; and
a second substrate unit including a glass layer, a first wiring layer and a second wiring layer disposed on a first surface and a second surface of the glass layer, respectively, an insulating layer disposed on the glass layer, and a third wiring layer disposed on the insulating layer, each of the first to third wiring layers including circuits,
wherein the second substrate unit is stacked on the first substrate unit or embedded in the first substrate unit,
wherein the first surface of the glass layer opposes the second surface of the glass layer, and
wherein an average pitch of the circuits of each of the first to third wiring layers is lower than an average pitch of the circuits of each of the plurality of build-up wiring layers.

2. The printed circuit board according to claim 1, wherein an average separation distance between adjacent layers among the first to third wiring layers is smaller than an average separation distance between adjacent layers among the plurality of build-up wiring layers.

3. The printed circuit board according to claim 2, wherein a thickness of each of the glass layer and the insulating layer is thinner than a thickness of each of the plurality of build-up insulating layers.

4. The printed circuit board according to claim 1, wherein the first substrate unit further comprises a plurality of build-up via layers, at least one of the plurality of build-up via layers penetrating through at least one of the plurality of build-up insulating layers,
the second substrate unit further comprises a first via layer penetrating through the glass layer and connecting the first and second wiring layers, and a second via layer penetrating through the insulating layer and connecting the first and third wiring layers,
each of the first and second via layers is tapered in a direction opposite a tapering direction of the plurality of build-up via layers as viewed in a cross-section of the printed circuit board, and
each of the plurality of build-up via layers, the first via layer, and the second via layer include a plurality of vias.

5. The printed circuit board according to claim 4, wherein at least one via among the plurality of vias in each of the plurality of build-up via layers, the first via layer, and the second via layer has a first end having a width wider than that of a second end opposing the first end, and as viewed in the cross-section of the printed circuit board, a width of the first end of the at least one via of each of the first and second via layers is narrower than a width of the first end of the at least one via of each of the plurality of build-up via layers.

6. The printed circuit board according to claim 4, wherein an average separation distance between adjacent vias among the plurality of vias in each of the first and second via layers is smaller than an average separation distance between adjacent vias among the plurality of vias in each of the plurality of build-up wiring layers.

7. The printed circuit board according to claim 4, wherein the first and second wiring layers and the first via layer are in direct contact with the glass layer.

8. The printed circuit board according to claim 1, wherein the glass layer includes plate glass.

9. The printed circuit board according to claim 8, wherein each of the insulating layer and the plurality of build-up insulating layers includes Ajinomoto Build-up Film (ABF), Prepreg (PPG), or a Photoimageable dielectric (PID).

10. The printed circuit board according to claim 1, further comprising:
first and second semiconductor chips disposed on the second substrate unit and interconnected to each other through the first to third wiring layers.

11. The printed circuit board according to claim 1, wherein the second substrate unit is stacked on an outermost build-up insulating layer among the plurality of build-up insulating layers to entirely cover the outermost build-up insulating layer.

12. The printed circuit board according to claim 1, wherein the second substrate unit is embedded in the first substrate unit, and a first outermost portion of the second substrate unit is exposed from an outermost surface of an outermost build-up insulating layer among the plurality of build-up insulating layers, and a side portion and a second outermost portion of the second substrate unit are embedded in the plurality of build-up insulating layers to be covered with the plurality of build-up insulating layers.

13. The printed circuit board according to claim 12, comprising a plurality of the second substrate units embedded in the plurality of build-up insulating layers.

14. A printed circuit board, comprising:
a first substrate unit comprising a plurality of build-up insulating layers and a plurality of build-up wiring layers respectively disposed on or in the plurality of build-up insulating layers; and
a second substrate unit comprising a glass layer, a first wiring layer and a second wiring layer disposed on a first surface and a second surface of the glass layer, respectively, an insulating layer disposed on the first surface of the glass layer, and a third wiring layer disposed on a surface of the insulating layer,
wherein the first surface of the glass layer opposes the second surface of the glass layer,
wherein the second substrate unit is stacked on or embedded in the first substrate unit, and
wherein a total thickness of the plurality of build-up insulating layers is thicker than a thickness of the insulating layer.

15. The printed circuit board according to claim 14, wherein the plurality of build-up insulating layers has more layers than the insulating layer.

16. The printed circuit board according to claim 14, wherein each of the plurality of build-up wiring layers includes a circuit, and each of the first to third wiring layers includes a circuit having a density that is higher than that of the circuit in each of the plurality of build-up wiring layers.

17. The printed circuit board according to claim 14, wherein the second substrate unit is stacked on the first substrate unit.

18. The printed circuit board according to claim 14, wherein the second substrate unit is embedded in the first substrate unit.

19. A printed circuit board, comprising:
a glass layer;
a first insulating layer disposed on a first surface of the glass layer;
a second insulating layer disposed on a second surface of the glass layer, wherein the second surface of the glass layer opposes the first surface of the glass layer;
a first wiring layer disposed between the glass layer and the first insulating layer;
a second wiring layer disposed on the second insulating layer; and
a first via layer penetrating through the glass layer and the second insulating layer collectively and connecting the first and second wiring layers.

20. The printed circuit board according to claim 19, further comprising:
a third wiring layer disposed on the first insulating layer; and
a second via layer penetrating through the first insulating layer and connecting the first and third wiring layers,
wherein the first via layer is deeper than the second via layer.
